(19) United States
(12) Patent Application Publication
(10) Pub. No.: US 2025/0076440 A1
(43) Pub. Date: Mar. 6, 2025

(54) 3D MEASUREMENTS USING TENSOR FIELD MAPPING

(71) Applicant: Q Bio, Inc., San Carlos, CA (US)

(72) Inventors: Jonathan Day Allen, Redwood City, CA (US); Matteo Alessandro Francavilla, San Mateo, CA (US); Thomas Witzel, Redwood City, CA (US); Jeffrey Howard Kaditz, Wilson, WY (US)

(21) Appl. No.: 18/826,951

(22) Filed: Sep. 6, 2024

Related U.S. Application Data
(60) Provisional application No. 63/580,952, filed on Sep. 6, 2023.

(51) Int. Cl. G01R 33/563; G01R 33/50; G01R 33/54

(52) U.S. Cl. CPC G01R 33/56308; G01R 33/50; G01R 33/546

(57) ABSTRACT

During operation, a computer system may perform magnetic-resonance (MR) measurements, where performing the MR measurements includes providing a radio-frequency (RF) sequence to an MR scanner. The RF sequence May include multiple instances of pulse sequences that correspond to a dynamic magnetization state in a sample, and a given pulse sequence may include more than a predefined number of pulses (such as 100 pulses). Then, the computer system may receive, from the MR scanner, information specifying the MR measurements. Next, the computer system may compute parameters associated with voxels in the sample based at least in part on the MR measurements, where computing the parameters may include solving an inverse problem for the parameters given the MR measurements, and where the RF sequence may encode second information in the MR measurements that allows the parameters for the voxels to be computed.

### CROSS-REFERENCE TO RELATED APPLICATION

This application claims priority under 35 U.S.C. § 119 (e) to: U.S. Provisional Application Ser. No. 63/580,952, entitled “3D Measurements Using Tensor Field Mapping,” by Jonathan Day Allen, et al., Attorney Docket Number TSLH-P25.00-P, filed on Sep. 6, 2023 the contents of which are herein incorporated by reference.

### FIELD

The described embodiments relate generally to techniques for acquiring three-dimensional (3D) measurements of a sample (as opposed to a set of two-dimensional (2D) slices of the sample).

### BACKGROUND

Many non-invasive characterization techniques are available for determining one or more physical parameters of a sample. For example, magnetic properties may be studied using magnetic resonance or MR (which is often referred to as ‘nuclear magnetic resonance’ or NMR), a physical phenomenon in which nuclei in a magnetic field absorb and re-emit electromagnetic radiation.

In typical magnet resonance imaging (MRI), a gradient magnetic field is applied in the z direction of a sample. This results in a variation in the resonance frequency of nuclear magnetic moments, which allows 3D properties of the sample to be measured using a set of 2D slices.

However, the set of 2D slices is not the same as 3D measurements of the sample. For example, the signal-to-noise ratio (SNR) is different. More generally, existing MRI techniques do not scale to 3D measurements.

### SUMMARY

A computer system that computes parameters associated with voxels in a sample is described. This computer system includes: an interface circuit; a processor that executes program instructions; and memory that stores the program instructions. During operation, the computer system performs MR measurements on the sample, where performing the MR measurements includes providing an RF sequence to an MR scanner. The RF sequence includes multiple instances of pulse sequences that correspond to a dynamic magnetization state in the sample, and a given pulse sequence includes more than a predefined number of pulses.

Then, the computer system receives, from the MR scanner, information specifying the MR measurements. Next, the computer system computes the parameters based at least in part on the MR measurements, where computing the parameters includes solving an inverse problem for the parameters given the MR measurements, and where the RF sequence encodes second information in the MR measurements that allows the parameters for the voxels to be computed.

Note that the predefined number of pulses may be greater than 100 pulses.

Moreover, the RF sequence may include time intervals between the instances of the pulse sequences.

Furthermore, the sample may be in a known magnetization state in each of the instances of the pulse sequence, and the known magnetization state may be different than magnetic polarization along an external magnetic field associated with the MR scanner (which is sometimes referred to as a ‘fully relaxed magnetic state’).

Additionally, the MR parameters in each of the voxels may include: a proton density, a longitudinal relaxation time or a spin-lattice relaxation time (T₁), and a transverse relaxation time or a spin-spin relaxation time (T₂).

In some embodiments, performing the MR measurements may include line encoding of different voxels in the sample. This may allow the Fourier or k-space-based properties of the sample in the dynamic magnetization state to be measured without perturbing the dynamic magnetization state.

Note that the dynamic magnetization state may correspond to three times a number of pulses in a given instance of the pulse sequence.

Another embodiment provides the MR scanner.

Another embodiment provides a system that includes the MR scanner and the computer system.

Another embodiment provides a computer-readable storage medium for use with the computer system. This computer-readable storage medium includes program instructions that, when executed by the computer system, causes the computer system to perform at least some of the aforementioned operations.

Another embodiment provides a method for computing parameters associated with voxels in a sample. This method includes at least some of the aforementioned operations performed by the computer system.

This Summary is provided for purposes of illustrating some exemplary embodiments, so as to provide a basic understanding of some aspects of the subject matter described herein. Accordingly, it will be appreciated that the above-described features are simply examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE FIGURES

FIG. 1 is a block diagram illustrating an example of a system in accordance with an embodiment of the present disclosure.

FIG. 2 is a flow diagram illustrating an example of a method for determining model parameters associated with a sample in accordance with an embodiment of the present disclosure.

FIG. 3 is a drawing illustrating an example of communication among components in the system in FIG. 1 in accordance with an embodiment of the present disclosure.

FIG. 4 is a drawing illustrating an example of a machine-learning model in accordance with an embodiment of the present disclosure.

FIG. 5 is a drawing illustrating an example of a neural model in accordance with an embodiment of the present disclosure.

FIG. 6 is a flow diagram illustrating an example of a method for computing parameters associated with voxels in a sample in accordance with an embodiment of the present disclosure.

FIGS. 7A-D are drawings illustrating examples of radio-frequency (RF) sequences and dynamic magnetization states used during Q Super Block (QSB) decomposition in the system in FIG. 1 in accordance with an embodiment of the present disclosure.

FIG. 8 is a block diagram illustrating an example of an electronic device in accordance with an embodiment of the present disclosure.

FIG. 9 is a drawing illustrating an example of a data structure that is used by the electronic device of FIG. 8 in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

Tensor Field Mapping (TFM) is a numerical framework for quantitative magnetic resonance imaging in the time domain. This method is based at least in part on building a numerical model for high-fidelity characterization of the signal detected in an MRI machine. This numerical model represents the forward model of a large-scale inverse problem, which enables solving for numerical multi-parameter tissue properties of a sample (such as a biological sample). Notably, the formulation yields a large scale, non-convex, numerical optimization problem. In order to make 3D problems tractable, a state-of-the-art numerical software framework is typically necessary.

These computational techniques may enable 3D measurements of the sample. For example, the RF sequence used in the MR measurements may facilitate Q Super Block or QSB decomposition. This capability may allow properties (such as parameters associated with voxels in the sample) to be efficiently computed using TFM. Consequently, the computation techniques may enable quantitative analysis of MR measurements, which may improve the usefulness of the MR measurements (e.g., in diagnosing and treating disease) and may significantly reduce the time needed to acquire the MR measurements. Thus, the computational techniques may improve overall user experience.

In the discussion that follows, MR measurements are used as an illustrative example of the computational techniques. In general, the computation techniques may be used in conjunction with a variety of characterization techniques that quantitatively simulate the response physics occurring within the sample to a given excitation. For example, the characterization techniques may involve: x-ray measurements (such as x-ray imaging, x-ray diffraction or computed tomography), neutron measurements (neutron diffraction), electron measurements (such as electron microscopy or electron spin resonance), optical measurements (such as optical imaging or optical spectroscopy that determines a complex index of refraction at one or more wavelengths), infrared measurements (such as infrared imaging or infrared spectroscopy that determines a complex index of refraction at one or more wavelengths), ultrasound measurements (such as ultrasound imaging), proton measurements (such as proton scattering), MR measurements or an MR technique (such as MRI, MR spectroscopy or MRS with one or more types of nuclei, magnetic resonance spectral imaging or MRSI, MR elastography or MRE, MR thermometry or MRT, magnetic-field relaxometry, diffusion-tensor imaging and/or another MR technique, e.g., functional MRI, metabolic imaging, molecular imaging, blood-flow imaging, etc.), impedance measurements (such as electrical impedance at DC and/or an AC frequency) and/or susceptibility measurements (such as magnetic susceptibility at DC and/or an AC frequency). Therefore, the excitation may include at least one of: an electromagnetic beam in an x-ray band of wavelengths (such as between 0.01 and 10 nm), a neutron beam, an electron beam, an electromagnetic beam in an optical band of wavelengths (such as between 300 and 800 nm), an electromagnetic beam in an infrared band of wavelengths (such as between 700 nm and 1 mm), a sound wave in an ultrasound band of wavelengths (such as between 0.2 and 1.9 mm), a proton beam, an electric field associated with an impedance measurement device, a radio-frequency (RF) wave associated with an MR apparatus or scanner, and/or a magnetic field associated with a susceptibility measurement device. However, another non-invasive characterization technique (such as positron emission spectroscopy), an integrated therapy (such as proton beam therapy or proton implantation, radiation therapy, magnetically guided nano particles, etc.) and/or a different range of wavelengths (such as ultraviolet wavelengths between 10 and 400 nm) may be used. In general, the computation techniques may be used with a wide variety of excitation may be used to ‘excite’ a region of space as long as there is a forward model that describes the response physics for these excitations.

Note that the sample may include an organic material or an inorganic material. For example, the sample may include: an inanimate (i.e., non-biological) sample, a biological lifeform (such as a person or an animal, i.e., an in-vivo sample), or a tissue sample from an animal or a person (i.e., a portion of the animal or the person). In some embodiments, the tissue sample was previously removed from the animal or the person. Therefore, the tissue sample may be a pathology sample (such as a biopsy sample), which may be formalin fixed-paraffin embedded. In the discussion that follows, the sample is a person or an individual, which is used as an illustrative example.

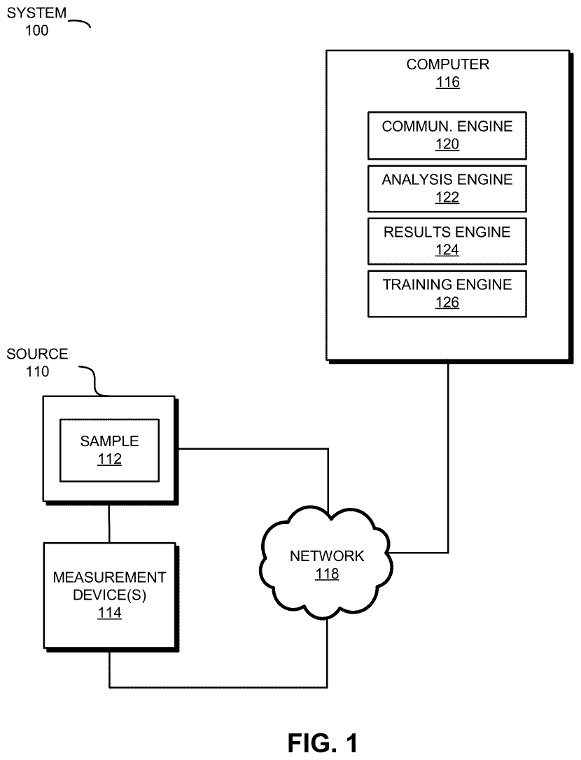

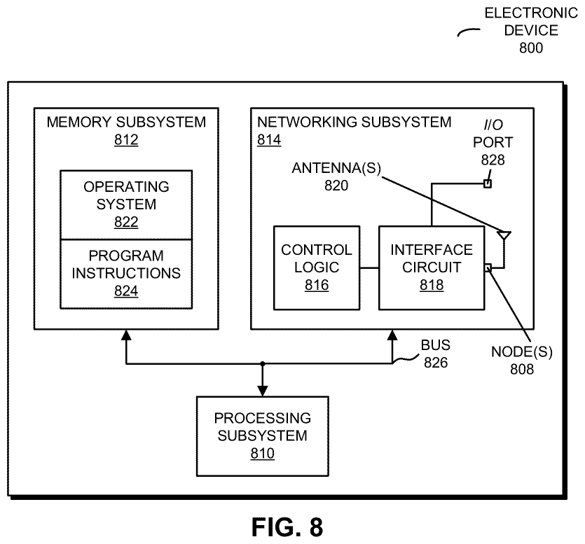

We now describe embodiments of a system. FIG. 1 presents a block diagram illustrating an example of a system 100. In system 100, a source 110 selectively provides an excitation to a sample 112, and a measurement device 114 selectively performs measurements on sample 112 to measure a response of sample 112 to the excitation. Moreover, system 100 includes a computer 116. As described further below with reference to FIG. 8, computer 116 may include subsystems, such as a processing subsystem, a memory subsystem and a networking subsystem. For example, the processing subsystem may include a processor that executes program instructions, the memory subsystem may include a memory that stores the program instructions, and networking subsystem may include an interface that communicates instructions or commands to source 110 and measurement device 114 (such as one or more sensors), that receives measurements from measurement device 114, and that selectively provides determined model parameters.

During operation, a communication engine (or module) 120 in computer 116 may provide, via a network 118 (such as one or more wired and/or wireless links or interconnects), an instruction or a command to source 110, which may cause source 110 to apply, to sample 112, the excitation. This excitation may have at least a wavelength and an intensity or a flux. For example, the excitation may include: electromagnetic radiation, a RF wave, a particle beam, a sound wave, a magnetic field, and/or an electric field.

In some embodiments, the excitation may include an external magnetic field that polarizes one or more types of nuclei in sample 112, an optional gradient in the magnetic field, and/or a RF pulse sequence (which are sometimes referred to as ‘measurement conditions’ or ‘scanning instructions’). Thus, source 110 may include a magnet that applies the external magnetic field, an optional gradient coil that applies the optional gradient, and/or a RF coil that applies the RF pulse sequence.

Then, communication engine 120 may provide, via network 118, an instruction or a command to measurement device 114, which may cause measurement device 114 to perform measurements of the response of at least a portion of sample 112 to the excitation. Moreover, measurement device 114 may provide, via network 118, the measurement results to communication engine 120. Note that measurement device 114 may include: an x-ray detector, a neutron detector, an electron detector, an optical detector, an infrared detector, an ultrasound detector, a proton detector, an MR apparatus or scanner, the impedance measurement device (such as a gel-covered table in an MR apparatus or scanner) and/or the susceptibility measurement device.

In some embodiments, measurement device 114 may include one or more RF pickup coils or another magnetic sensor (such as a magnetometer, a superconducting quantum interference device, opto-electronics, etc.) that measure time-varying or time-domain electrical signals corresponding to the dynamic behavior of nuclear spins in the one or more types of nuclei or at least an average component of the magnetization corresponding to the aggregate dynamic behavior of the nuclear spins (which is sometimes referred to as a ‘magnetic response’) of at least the portion of sample 112. For example, measurement device 114 may measure the transverse magnetization of at least a portion of sample 112 as it precesses in the xy plane.

Note that the measurements provided by measurement device 114 may be other than or different from an image. For example, the measurements may be other than MRI results. For example, the measurements may include or may correspond to (such as one or more components of) a free-induction-decay of the nuclear spins in sample 112. Consequently, in some embodiments the measurements may not involve performing a Fourier transform on the measured electrical signals (and, thus, may not be performed in k-space and may not involve pattern matching in k-space, such as MR fingerprinting). However, in general, the measurements may be specified in the time domain and/or the frequency domain. Therefore, in some embodiments, a variety of signal processing (such as filtering, image processing, etc.), noise cancellation and transformation techniques (such as a discrete Fourier transform, a Z transform, a discrete cosine transform, data compression, etc.) may be performed on the measurements.

After receiving the measurements, analysis engine (or module) 122 in computer 116 may analyze the measurements. This analysis may involve determining a (possibly time-varying) 3D position of sample 112 relative to measurement device 114 (which is sometimes referred to as ‘3D registration information’). For example, the aligning may involve performing point-set registration, such as with reference markers at known spatial locations. The registration may use a global or a local positioning system to determine changes in the position of sample 112 relative to measurement device 114. Alternatively or additionally, the registration may be based at least in part on variation in the Larmor frequency and the predetermined spatial magnetic-field inhomogeneity or variation in the magnetic field of source 110 and/or measurement device 114 (such as an MR apparatus or scanner). In some embodiments, the analysis involves aligning the voxels based at least in part on the registration information with desired voxel locations, and/or resampling and/or interpolating the measured signals to different voxel locations, which may facilitate subsequent comparisons with previous measurements or results.

Moreover, analysis engine 122 may use the measurements to determine model parameters for a forward model with multiple voxels that represent sample 112, and that simulates the response physics occurring in sample 112 to a given excitation in a range of possible excitations (i.e., the forward model may be more general than one that determines the predicted response to a particular or a specific excitation). Notably, with the appropriate model parameters for the voxels in sample 112, analysis engine 122 may use the forward model to accurately and quantitatively simulate or calculate a predicted response of sample 112 to the excitation (such as a predicted component of the magnetization). Note that the forward model may be based at least in part on or may use one or more differential equations or one or more phenomenological equations that approximate the response physics of sample 112 on a voxel-by-voxel basis. For example, the forward model may be based at least in part on or may use the Bloch equations, the Bloch-Torrey equations (thus, the forward model may include simulations of dynamics, such as motion associated with: respiration, a heartbeat, blood flow, mechanical motion, etc.), full Liouvillian computations (such as a Liouville supermatrix of interactions between two or more elements), a full Hamiltonian, Maxwell's equations (e.g., the forward model may calculate magnetic and electrical properties of sample 112), thermal diffusion equations, the Pennes equations, and/or another simulation technique that represents the physics of a response of sample 112 to a type of excitation. Because in some embodiments the assumptions underlying the Bloch equations are invalid (such as the parallel and antiparallel components of the magnetization are coupled, e.g., when the state of the magnetization is not reset prior to an RF pulse sequence), additional error terms may be added to the Bloch equations. Therefore, the forward model may be able to compute a dynamic (e.g., time-varying) state of sample 112 in response to an arbitrary excitation in a range of possible excitations or excitation values.

In some analysis approaches, computer 116 may determine the model parameters by solving an inverse problem by iteratively modifying the model parameters associated with the voxels in the forward model until a difference between the predicted response and the measured dynamic magnetic response is less than a predefined value (such as 0.1, 1, 5 or 10%). (Note that ‘an inverse problem’ starts with one or more result(s) or output(s) and then calculates the inputs or causes. This is the inverse of a ‘forward problem,’ which starts with the inputs and then calculates the one or more results or the outputs.) However, in this ‘iterative approach,’ source 110 may repeatedly apply different excitations, and measurement device 114 may repeatedly perform corresponding measurements. Consequently, the iterative approach may be time-consuming, expensive and complicated. Thus, the iterative approach may consume significant resources in system 100 until the appropriate model parameters are determined.

In order to address these problems, in the computation techniques analysis engine 122 may use one or more predetermined or pretrained predictive models (such as a machine-learning model or a neural network, which may be specific to a particular sample or an individual, e.g., the predictive model may be a personalized predictive model) to, at least in part, compute the model parameters on a voxel-by-voxel basis. For example, analysis engine 122 may use the measurements and information specifying the excitation as inputs to a predictive model, which provides, as an output, the model parameters associated with the voxels. Therefore, the predictive model may be trained on or may incorporate model-parameter information based at least in part on measurements or measurement results. In some embodiments, the predictive model may correct the measurements for extrinsic characteristics or a signature of a specific source 110 and/or measurement device 114 (such as RF noise or spatial magnetic-field inhomogeneity) and/or a particular excitation or measurement condition, so that the determined model parameters are intrinsic to sample 112 at a particular time when the measurements were performed.

Note that the model parameters may include: T₁ (which is the time constant associated with the loss of signal intensity as components of the nuclear-spin magnetization vector of a type of nuclei relax to be parallel with the direction of an external magnetic field), T₂ (which is the time constant associated with broadening of the signal during relaxation of components of the nuclear-spin magnetization vector of a type of nuclei perpendicular to the direction of the external magnetic field), an adjusted spin-spin relaxation time T₂*, proton or nuclei density (and, more generally, the densities of one or more type of nuclei), diffusion (such as components in a diffusion tensor), velocity/flow, temperature, off-resonance frequency, electrical conductivity or a dielectric constant, and/or a magnetic susceptibility or permittivity.

If a subsequent simulation using these model parameters provided by the predictive model, the forward model and one or more excitations of one or more predicted responses of sample 112 (such as a simulated or predicted MR signal) agrees with the corresponding measurements (such as a difference between a predicted response and a measurement is less than a predefined value, e.g., 0.1, 1, 5 or 10%, or alternatively when an accuracy exceeds a predefined value), results engine (or module) 124 in computer 116 may provide the determined model parameters, such as by providing an output to a user, to another electronic device, to a display and/or to the memory. In some embodiments, results engine 124 may output a tensor field map for sample 112 with model parameters for 3 spatial x one temporal x up to N measurement dimensions, where each measurement may be a vector or scalar quantity.

Thus, when the accuracy exceeds the predefined value (such as 90, 95, 99 or 99.9%), the model parameters may be computed in a single pass without further iteration. Consequently, the model parameters having an accuracy exceeding the predefined value may be computed using fewer (or no) iterations with the predetermined predictive model (and, thus, more rapidly) than in the iterative approach without the predetermined predictive model.

Alternatively, when the accuracy is less than the predefined value, computer 116 may perform one or more iterations in which one or more different, modified or revised excitations (such as a different RF pulse sequence) are applied to sample 112 by source 114, and one or more corresponding additional measurements are performed by measurement device 114. These one or more additional measurements may be used by computer 116 to determine the model parameters with an accuracy less than the predefined value.

For example, analysis engine 122 may use a second predetermined predictive model (such as a second machine-learning model or a second neural network) to determine a revised excitation. Notably, using information specifying the excitation and the accuracy as inputs, the second predictive model may output the revised excitation. Then, system 100 may repeat the applying, measuring, computing and determining operations with the revised excitation instead of the excitation. Therefore, the second predictive model may be trained on or may incorporate excitation information based at least in part on remaining differences between the predicted response and the measurement in order to reduce or eliminate the remaining differences in one or more subsequent iterations of the operations performed by system 100. In some embodiments, the second predictive model may revise a sampling frequency, a characterization technique, etc. to determine additional information that allows the determination of the model parameters using the first predictive model to converge (i.e., to have an accuracy less than the predefined value). Stated differently, the next perturbation or disturbance may be chosen to minimize the error or the difference across the hyper-dimensional space.

In some embodiments, when the accuracy is less than the predefined value, training engine (or module) 126 in computer 116 may: add the excitation and the measured response to a training dataset; and determine, using the training dataset, a revised instance of the predictive model for subsequent use in determining the model parameters. Thus, the measurements performed by system 100 may be selectively used in an adaptive learning technique to improve the predictive model and, therefore, the determined model parameters for a range of excitations (such as different values of the wavelength and the intensity or the flux).

Using the model parameters and the forward model, analysis engine 122 may simulate or predict a response of sample 112 to an arbitrary excitation, such as an arbitrary external magnetic field strength or direction (such as 0 T, 6.5 mT, 1.5 T, 3 T, 4.7 T, 9.4 T, and/or 15 T, or a time-varying direction, e.g., a slowly rotating external magnetic field), an arbitrary optional gradient, an arbitrary pulse sequence, an arbitrary magnetic state or condition (e.g., in which the magnetization or polarization of sample 112 is not returned to, been reset to or re-magnetized to an initial state prior to a measurement), etc. Therefore, the model parameters and the forward model may be used to facilitate fast and more accurate measurements, such as: soft-tissue measurements, morphological studies, chemical-shift measurements, magnetization-transfer measurements, MRS, measurements of one or more types of nuclei, Overhauser measurements, and/or functional imaging. For example, in embodiments where computer 116 determines the model parameters concurrently with measurements performed on sample 112 by source 110 and measurement device 114 (i.e., in real time), system 100 may rapidly characterize one or more physical parameters of sample 112 (at the voxel level or on average) on time scales smaller than T₁ or T₂ in an arbitrary type of tissue. This capability may allow system 100 to perform initial measurements to determine the model parameters, and then to use the determined model parameters to simulate or predict MR signals to complete or fill in ongoing measurements being performed by system 100, so that the results may be obtained more rapidly (and, thus, with a shorter MR scan time). Note that, in some embodiments, system 100 may determine the results (such as detecting an anomaly or a change in sample 112) based at least in part on quantitative comparisons of previous results obtained on sample 112, such as stored model parameters for the voxels in sample 112 that were determined during a previous MR scan(s) of sample 112. Such comparisons may be facilitated by 3D registration information that allows the voxel positions in sample 112 at different times to be aligned. In some embodiments, the results are based at least in part on a physician's instructions, medical lab test results (e.g., a blood test, urine-sample testing, biopsies, genetic or genomic testing, etc.), an individual's medical history, the individual's family history, quantitative tensor field maps with voxel-dependent multi-dimensional data for sample 112 or other samples, impedance of sample 112, a hydration level of sample 112 and/or other inputs.

Furthermore, in some embodiments analysis engine 122 may classify or segment one or more anatomical structures in sample 112 using the determined model parameters and a third predetermined predictive model (such as a third machine-learning model and/or a third neural network). For example, using the simulated or predicted response of sample 112 at the voxel level or the determined model parameters at the voxel level, the third predictive model may output the locations of different anatomical structures and/or may output classifications of different voxels (such as a type of organ, whether they are associated with a particular disease state, e.g., a type of cancer, a stage of cancer, etc.). Therefore, in some embodiments, the third predictive model may be trained on or may incorporate classification of segmentation information based at least in part on variation in the model parameters across boundaries between different voxels (such as discontinuous changes). This capability may allow analysis engine 122 to identify different anatomical structures (which may assist in the determination of the model parameters) and/or to diagnose or to make a diagnosis recommendation about a medical condition or a disease state. In some embodiments, the classification or segmentation is performed prior to, concurrently or following the determination of the model parameters.

In some embodiments, training engine 126 may have, at least in part, trained the predictive model, the second predictive model and/or the third predictive model using a simulated dataset. For example, training engine 126 may have generated the simulated dataset using the forward model, a range of model parameters and a range of excitations. In this way, simulated data may be used to accelerate training of one or more predictive models.

Notably, because the computation techniques may capture all relevant information during the measurements (such as an MR scan), the forward model may be used in an off-line mode to curate an extensive, labeled dataset that includes a large number of possible scenarios (such as different measurement conditions). This database may then be used to train predictive models. This capability may address the difficulty in obtaining MR data that is accurately labeled, reproducible, and artifact-free.

In conjunction with the generated dataset, one or more predictive models may be used to select regularization that accelerates the initial data acquisition and/or denoising. Moreover, the one or more predictive models may also be used to accelerate simulations or reconstruction using the forward model. For example, a predictive model may provide initial model parameters for use in the forward model, which may reduce the number of iterations required for the measurements and the simulations to converge on a solution that has an accuracy exceeding the predefined value. Thus, if the initial model parameters result in predicted response that are very different from the measurements, this may be feedback into the subsequent measurements and simulations to improve the model parameters and, thus, the predicted response.

Furthermore, if there is a portion of the model-parameter space that is not covered by the predictive model(s), new data points may be accurately generated and labeled to train the predictive model(s). Additionally, the predictive model(s) may be trained based on different metrics corresponding to different applications. For example, the predictive model(s) may be training to optimize the excitations used in difference scenarios (such as fast scanning for asymptomatic population, high accuracy for specific tissue properties, robustness to variations in the SNR, different hardware imperfections, etc.).

In some embodiments, analysis engine 122 may run a neural network that determines first model parameters based at least in part on measured or simulated data and may performs brute-force nonlinear numerical calculations to solve an inverse problem using the measured or the simulated data to determine second model parameters. The difference between the first and the second model parameters from these two ‘inverse solvers’ may be used as the error in the neural-network-based approach. This approach may allow the neural network to learn because the numerical approach may be able to give real-time feedback to the neural network and to back propagate/update the weights in the neural network. This hybrid approach would still not require or need a priori training, but would be able to leverage the pattern-matching benefits of large neural networks with the determinism and accuracy of simulation/numerical techniques to solve the inverse problem. The hybrid approach may assist the neural network when it has an input unlike any of the examples used to train it. Similarly, the hybrid approach may be used to go directly from time-domain measurement to the model-parameterized output (i.e. the inverse problem outputs). In some embodiments, the hybrid approach is implemented using a generative adversarial network (GAN).

Note that, in some embodiments, the forward model may be independent of a particular MR apparatus or scanner. Instead, the forward model may be, e.g., specific to an individual. The predicted response computed using the forward model may be adjusted to include characteristics or a signature of a particular MR apparatus or scanner, such as magnetic-field inhomogeneity or spatial variation in the magnetic field, RF noise, a particular RF pickup coil or another magnetic sensor, variation in the characteristics or the signature with the external magnetic-field strength or the measurement conditions (such as the voxel size), geographic location, time (due to, e.g., magnetic storms), etc. Thus, the predicted response may or may not be machine-specific.

While the preceding discussion illustrated the computation techniques using a single predictive model for sample 112, in other embodiments there may be multiple predictive models for sample 112. For example, different predictive models may be used to determine the model parameters for different portions of sample 112 (such as different organs or different types of tissue) and, thus, for different voxels. Therefore, in some embodiments different predictive models may be used to provide T₁ and T₂ values in different types of tissue, such as the values summarized in Table 1.

TABLE 1

| Tissue | T₁ (s) | T₂ (ms) |
|---|---|---|
| Cerebrospinal Fluid | 0.8-20 | 110-2000 |
| White Matter | 0.76-1.08 | 61-100 |
| Gray Matter | 1.09-2.15 | 61-109 |
| Meninges | 0.5-2.2 | 50-165 |
| Muscle | 0.95-1.82 | 20-67 |
| Adipose | 0.2-0.75 | 53-94 |

Moreover, while system 100 is illustrated as having particular components, in other embodiments system 100 may have fewer or more components, two or more components may be combined into a single component, and/or positions of one or more components may be changed.

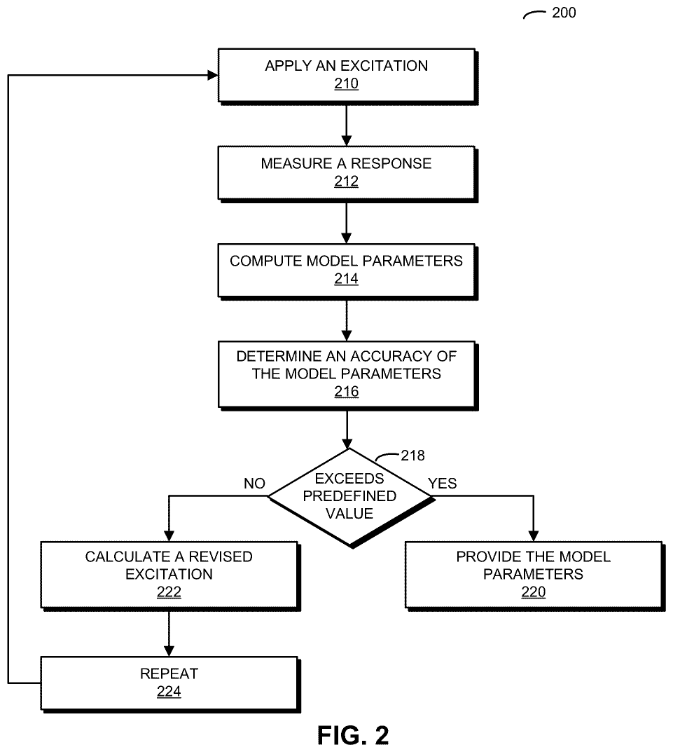

We now embodiments of a method. FIG. 2 presents a flow diagram illustrating an example of a method 200 for determining model parameters associated with a sample. This method may be performed by a system (such as system 100 in FIG. 1), or one or more components in a system (such as source 110, measurement device 114 and/or computer 116).

During operation, a source in the system may apply, to the sample, an excitation (operation 210), where the excitation has at least a wavelength and an intensity or a flux. For example, the excitation may include one of: electromagnetic radiation, a RF wave, a particle beam, a sound wave, a magnetic field, and/or an electric field. Therefore, the excitation may include at least one of: an electromagnetic beam in an x-ray band of wavelengths, a neutron beam, an electron beam, an electromagnetic beam in an optical band of wavelengths, an electromagnetic beam in an infrared band of wavelengths, a sound wave in an ultrasound band of wavelengths, a proton beam, an electric field associated with an impedance measurement device, a RF wave associated with a magnetic-resonance apparatus, and/or a magnetic field associated with a susceptibility measurement device.

Then, a measurement device in the system may measure a response (operation 212) associated with the sample to the excitation. For example, the measurement device may include at least one of: an x-ray detector, a neutron detector, an electron detector, an optical detector, an infrared detector, an ultrasound detector, a proton detector, the magnetic-resonance apparatus, the impedance measurement device and/or the susceptibility measurement device. Note that the measured response may include a time-domain response of the sample and may be other than or different from an image.

Moreover, the system may compute, using the measured response and information specifying the excitation as inputs to a predetermined predictive model, model parameters (operation 214) on a voxel-by-voxel basis in a forward model with multiple voxels that represent the sample. The forward model may simulate response physics occurring within the sample to a given excitation with a given wavelength and a given intensity or a given flux, that are selected from a range of measurement conditions that includes the excitation, the wavelength and the intensity or the flux, and at least a different wavelength and a at least a different intensity or a different flux. Furthermore, the forward model may be a function of the excitation, the model parameters of the multiple voxels, and differential or phenomenological equations that approximates the response physics.

Note that the predetermined predictive model may include a machine-learning model and/or a neural network. In some embodiments, the predetermined predictive model includes a personalized predictive model that corresponds to an individual.

Next, the system may determine an accuracy of the model parameters (operation 216) by comparing at least the measured response and a calculated predicted value of the response using the forward model, the model parameters and the excitation.

Additionally, when the accuracy exceeds a predefined value (operation 218), the system may provide the model parameters (operation 220) as, e.g., an output to a user, to another electronic device, to a display and/or to the memory.

Thus, when the accuracy exceeds the predefined value (operation 218), the model parameters may be computed in a single pass without further iteration. Consequently, the model parameters having an accuracy exceeding the predefined value may be computed using fewer iterations with the predetermined predictive model than in the iterative approach without the predetermined predictive model.

Alternatively, when the accuracy is less than the predefined value (operation 218), the system may: calculate, using information specifying the excitation and the accuracy as inputs to a second predetermined predictive model, a revised excitation (operation 222) that has at least a revised wavelength, a revised intensity or a revised flux; and repeat (operation 224) the applying, measuring, computing and determining operations with the revised excitation instead of the excitation. Note that the second predetermined predictive model may include a machine-learning model and/or a neural network.

In some embodiments, the system optionally performs one or more optional additional or alternative operations. For example, when the accuracy is less than the predefined value (operation 218), the system may: add the excitation and the measured response to a training dataset; and determine, using the training dataset, a revised instance of the predictive model.

Additionally, the system may classify or segment one or more anatomical structures in the sample using the model parameters and a third predictive model. For example, the third predetermined predictive model may include a machine-learning model and/or a neural network.

Moreover, the system may train the predictive model using a simulated dataset computed using the forward model, a range of model parameters and a range of excitations.

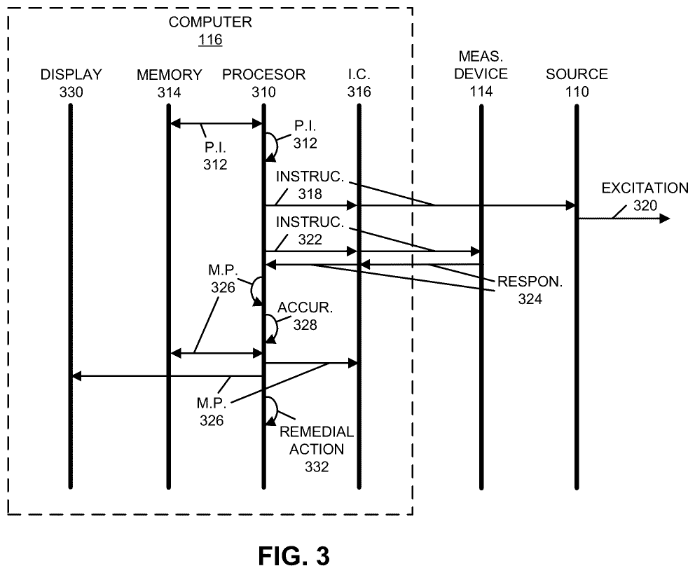

FIG. 3 presents a drawing illustrating an example of communication among components in system 100 (FIG. 1). Notably, processor 310 in computer 116 may execute program instructions (P.I.) 312 stored in memory 314. When processor 310 executes program instructions 312, processor 310 may perform at least some of the operations in the computation techniques.

During the computation technique, processor 310 may provide instruction 318 to interface circuit (I.C.) 316. In response, interface circuit 316 may provide instruction 318 to source 110, e.g., in one or more packets or frames. Moreover, after receiving instructions 318, source 110 may apply, to the sample, an excitation 320.

Then, processor 310 may provide instruction 322 to interface circuit 316. In response, interface circuit 316 may provide instruction 322 to measurement device 114, e.g., in one or more packets or frames. Furthermore, after receiving instructions 322, measurement device 114 may measure a response 324 associated with the sample to excitation 320. Next, measurement device 114 may provide measured response 324 to computer 116, e.g., in one or more packets or frames.

After receiving measured response 324, interface circuit 316 may provide measured response 324 to processor 310. Then, using measured response 324 and information specifying excitation 320 as inputs to a predetermined predictive model, processor 310 may compute model parameters (M.P.) 326 on a voxel-by-voxel basis in a forward model with multiple voxels that represent the sample.

Additionally, processor 310 may determine an accuracy 328 of the model parameters by comparing at least measured response 324 and a calculated predicted value of the response using the forward model, model parameters 326 and excitation 320. When accuracy 328 exceeds a predefined value, processor 310 may provide the model parameters 326 as, e.g., an output to a user, to another electronic device (via interface circuit 316), to a display 330 and/or memory 314.

Otherwise, when the accuracy is less than the predefined value, processor 310 may perform a remedial action 332. For example, processor 310 may: calculate, using information specifying excitation 320 and accuracy 328 as inputs to a second predetermined predictive model, a revised excitation; and repeat the applying, measuring, computing and determining operations with the revised excitation instead of excitation 320. Alternatively or additionally, processor 310 may: add excitation 320 and measured response 324 to a training dataset; and determine, using the training dataset, a revised instance of the predictive model.

While communication between the components in FIG. 3 is illustrated with unilateral or bilateral communication (e.g., lines having a single arrow or dual arrows), in general a given communication operation may be unilateral or bilateral. Moreover, while FIG. 3 illustrates operations being performed sequentially or at different times, in other embodiments at least some of these operations may, at least in part, be performed concurrently or in parallel.

We now describe embodiments of predictive models. For example, a predictive model may include a machine-learning model, such as a supervised-learning model or an unsupervised learning technique (such as clustering). In some embodiments, a machine-learning model may include: a support vector machine, a classification and regression tree, logistic regression, LASSO, linear regression, nonlinear regression, pattern recognition, a Bayesian technique, and/or another (linear or nonlinear) supervised-learning technique.

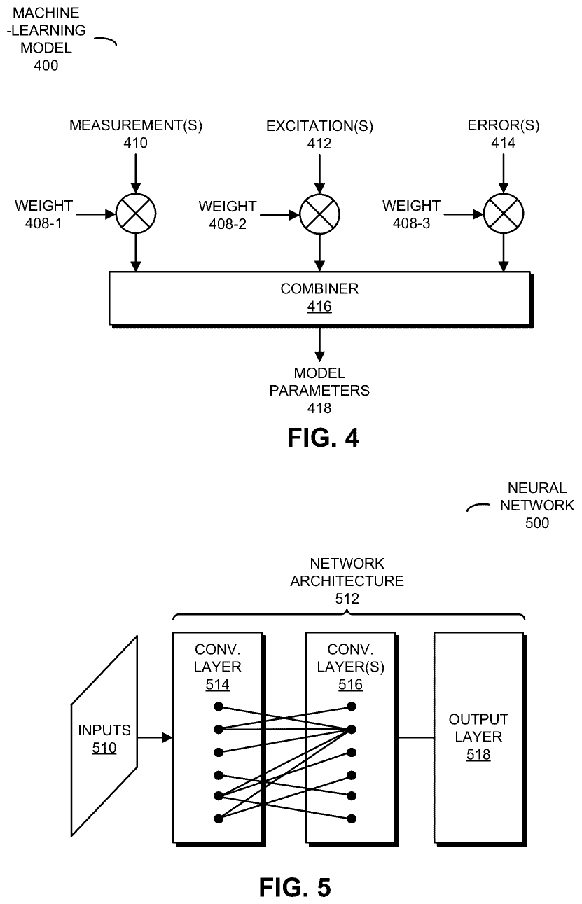

FIG. 4 presents a drawing illustrating an example of a machine-learning model 400. In this machine-learning model, a weighted (using weights 408) linear or nonlinear combination 416 of measurements 410, one or more corresponding excitations 412 and one or more errors 414 between the one or more measurements 410 and one or more predicted responses determined using a forward model, a current instance of the model parameters of voxels in the forward model, and the one or more excitations 412 is used to compute a revised instance of model parameters 418. Thus, in some embodiments, predictive model 400 is used in conjunction with forward model to iteratively modify instances of the model parameters until an accuracy of the predicted response is less than a predefined value (i.e., a convergence criterion is achieved). However, in some embodiments, a machine-learning model may be used to determine the model parameters in one pass, i.e., in an open-loop manner.

Alternatively or additionally, a predictive model may include a neural network. Neural networks are generalized function approximators. For example, techniques such as deep learning typically use previous examples as inputs. In general, it is not possible for these machine-learning models to determine the actual function they are trying to approximate because there is no reference point for them to use to estimate the error in their predictions. In particular, it may be difficult for a neural network to make predictions based on an input that is very different from the examples it was trained on. In this regard, a neural network may be thought of as a lossy compute compression engine.

However, by training a neural network using a wide variety of excitations, measured responses and corresponding model parameters, the neural network may provide the model parameters (or initial estimates of the model parameters) for a forward model that simulates the physics of a response of a sample to an excitation. Because neural networks are effective approximations/compressions, they may execute faster on the same inputs with less computational power required. Moreover, because the functions are known in the forward model, the responses may be computed and the accuracy of the predictions may be assessed (as opposed to using an approximation). Therefore, the computation technique may be used to determine when its predictions are unreliable. In particular, as discussed previously for FIG. 4, a neural network may be used in conjunction with forward model to iteratively modify instances of the model parameters until an accuracy of the predicted response is less than a predefined value (i.e., a convergence criterion is achieved). In some embodiments, however, a neural network may be used to determine the model parameters in one pass, i.e., in an open-loop manner.

FIG. 5 presents a drawing illustrating an example of a neural network 500. This neural network may be implemented using a convolutional neural network or a recurrent neural network. For example, neural network 500 may include a network architecture 512 that includes: an initial convolutional layer 514 that provides filtering of inputs 510 (such as one or more measurements and a difference or an error between the one or more measurements and one or more predicted responses determined using a forward model, a current instance of model parameters and an excitation); an additional convolutional layer(s) 516 that apply weights; and an output layer 518 (such as a rectified linear layer) that performs selection (e.g., selecting a revised instance of the model parameters). Note that the details with the different layers in neural network 500, as well as their interconnections, may define network architecture 512 (such as a directed acyclic graph). These details may be specified by the instructions for neural network 500. In some embodiments, neural network 500 is reformulated as a series of matrix multiplication operations. Neural network 500 may be able to handle the real-world variance in 1 million inputs or more. Note that neural network 500 may be trained using a deep-learning technique or a GAN. In some embodiments of machine-learning model 400 (FIG. 4) and/or neural network 500, a current instance of the model parameters is used as an input.

In some embodiments, a large convolutional neural network may include 60 M parameters and 650,000 neurons. The convolutional neural network may include eight learned layers with weights, including five convolutional layers and three fully connected layers with a final 1000-way softmax or normalized exponential function that produces a distribution over the 1000 class labels for different possible model parameters. Some of the convolution layers may be followed by max-pooling layers. In order to make training faster, the convolutional neural network may use non-saturating neurons (such as a local response normalization) and an efficient dual parallelized graphics processing unit (GPU) implementation of the convolution operation. In addition, in order to reduce overfitting in the fully-connected layers, a regularization technique (which is sometimes referred to as ‘dropout’) may be used. In dropout, the predictions of different models are efficiently combined to reduce test errors. In particular, the output of each hidden neuron is set to zero with a probability of 0.5. The neurons that are ‘dropped out’ in this way do not contribute to the forward pass and do not participate in backpropagation. Note that the convolutional neural network may maximize the multinomial logistic regression objective, which may be equivalent to maximizing the average across training cases of the log-probability of the correct label under the prediction distribution.

In some embodiments, the kernels of the second, fourth, and fifth convolutional layers are coupled to those kernel maps in the previous layer that reside on the same GPU. The kernels of the third convolutional layer may be coupled to all kernel maps in the second layer. Moreover, the neurons in the fully connected layers may be coupled to all neurons in the previous layer. Furthermore, response-normalization layers may follow the first and second convolutional layers, and max-pooling layers may follow both response-normalization layers as well as the fifth convolutional layer. A nonlinear model of neurons, such as Rectified Linear Units, may be applied to the output of every convolutional and fully-connected layer.

In some embodiments, the first convolutional layer filters a 224×224×3 input image with 96 kernels of size 11×11×3 with a stride of four pixels (this is the distance between the receptive field centers of neighboring neurons in a kernel map). Note that the second convolutional layer may take as input the (response-normalized and pooled) output of the first convolutional layer and may filter it with 256 kernels of size 5×5×48. Furthermore, the third, fourth, and fifth convolutional layers may be coupled to one another without any intervening pooling or normalization layers. The third convolutional layer may have 384 kernels of size 3×3×256 coupled to the (normalized, pooled) outputs of the second convolutional layer. Additionally, the fourth convolutional layer may have 384 kernels of size 3×3×192, and the fifth convolutional layer may have 256 kernels of size 3×3×192. The fully-connected layers may have 4096 neurons each. Note that the numerical values in the preceding and the remaining discussion below are for purposes of illustration only, and different values may be used in other embodiments.

In some embodiments, the convolutional neural network is implemented using at least two GPUs. One GPU may run some of the layer parts while the other runs the remaining layer parts, and the GPUs may communicate at certain layers. The input of the convolutional neural network may be 150,528-dimensional, and the number of neurons in the remaining layers in the convolutional neural network may be given by 253, 440-186, 624-64, 896-64, 896-43, and 264-4096-4096-1000.

We now further described the computational techniques.

### The Forward Model

In an MRI experiment, the signal sᵢ detected by the ith receiving coil is proportional to

$${S}_{i} ( t ) = {\int }_{V}^{} \overline{{B}_{l , ι}} ( r ) \cdot D ( r ) \overline{m} ( r , t ) dr , \qquad ( 1 )$$

where B̅_̅{̅l̅,̅t̅}̅(r) denotes the spatially dependent ith coil sensitivity, D is the proton density, and m̅(r,t) is the magnetization vector.

A receiving coil may be any electric structure capable of measuring a time-varying magnetic field. Examples include, but are not limited to: an arbitrarily shaped closed loop of conducting wire; and/or multiple and partially overlapping loops of conducting wires, which may include lumped reactive elements (capacitors and inductors). If the receiving coil is tuned to resonate at the Larmor frequency f₀, B̅_̅{̅l̅,̅ι̅}̅(r) acts as a band-pass filter and selects frequencies close to f₀, which for a typical MRI apparatus or hardware is in the range of 1-300 MHz. For example, for a 0.5T MRI apparatus or scanner, f₀ is approximate 21 MHz. Because the magnetization m̅ may be decomposed into transverse and axial components as m̅=mₜ\hat{t}+m_{z}\hat{z}, and because, for a typical MRI experiment, m(t) oscillates around the Larmor frequency, Eqn. (1) is often simplified to only consider transverse magnetizations (the axial component m_{z} does not convey frequency content around f₀).

In order to measure the signal in Eqn. (1) at an arbitrary location r̅ₙ̅, if the magnetic field time distribution B̅(rₙ,t) is known, one may make use of the Bloch equations, a set of differential equations that describe the behavior of the nuclear spins in a magnetic field

$$\frac{d}{dt} \overline{m} = γ \overline{m} x \overline{B} - \frac{1}{{T}_{2}} {m}_{t} - \frac{1}{{T}_{1}} ( {m}_{z} - {m}_{0} ) z , \qquad ( 2 )$$

where m₀ denotes the equilibrium axial magnetization and B̅(t) is the net magnetic field seen at each location. In general, B̅(t) may be decomposed into three dominant contributions

$$\overline{B} ( t ) = {B}_{0} + Δ B + \overline{{B}_{ι}^{+}} ( t ) + \overline{G} ( t ) \cdot \overline{r} ,$$

where B₀+ΔB is the static field due to the main (superconducting or permanent) magnet assembly, B̅ₗ̅⁺̅(t) is the RF field generated by the transmit coils, and G̅ is a dyadic operator representing the contribution from the gradient system. Often, in MRI systems, the dyad G̅ is approximated as \hat{z}\hat{x}Gₓ+\hat{z}\hat{z}G_{y}+\hat{z}\hat{z}G_{z} (the transverse component of the field produced by the gradient coils is neglected). Note that the explicit dependency of G̅ and B̅ₗ̅⁺̅(t) on the temporal variable t refers to the fact that gradient coils and RF pulses in an MRI experiment are controlled during the acquisition, and their exact form is a feature of each specific acquisition strategy (e.g., the pulse sequence).

### TFM

The TFM forward model may include: hardware modeling, pulse-sequence compilation, and per-voxel computation. During hardware modeling, the hardware is characterized in order to model quantities such as ΔB (the static field in-homogeneity), B̅ₗ̅⁺̅(t) (the RF transmit field), B̅ₗ̅⁻̅(the receiving coil sensitivities), and G̅ (the gradient coils model). This operation may only depend on the hardware, and may not depend on the sample or on the acquisition strategy (such as the TFM pulse sequence).

Moreover, during pulse-sequence compilation, the pulse sequence may be compiled and quantities related to the sequence may be precomputed. This operation may explicitly depend on the pulse sequence and on the hardware characterization, but is independent from the sample.

A pulse sequence may be represented as a list of blocks, where each block may include: an RF pulse; an optional gradient waveform on one or more gradient coils; and/or an optional readout window during which the signal is sampled. For each block, the generalized gradients may be computed and cached at different time points: from to (the beginning of the block) to ^{t}RF (the RF pulse); from ^{t}RF to ^{t}E (the echo time, which is interpreted as the center of the acquisition window); from ^{t}E to ^{t}end (the end of the block); and/or from ^{t}E to tₛ, where tₛ is a list of (typically equi-spaced) timepoints, at which the signal is sampled and collected. This operation may propagate the signal from the center of the acquisition window to the entire acquisition window.

Each generalized gradient may be stored as a pair (T,M), where T=t₂−t₁ is the temporal duration and M=∫ₜ_{₁}^{t}^{₂}G̅(t)·r̅dr is the gradient moment.

Additionally, the effect of each RF pulse may be precomputed and stored as a rotation matrix to be applied to the magnetization vector. The rotation and relaxation are orthogonal over short durations and therefore may be applied separately, which is a reasonable and commonly adopted assumption because of the negligible duration of an RF pulse (T_{RF} is approximately 5 ms) with respect to the relaxation times (T₁, T₂ are typically greater than 100 ms). The rotation matrix may only depend on the RF amplitude (Bₗ⁺, the ideal flip angle) and the off-resonance (ΔB, the gradient amplitude). A look-up table of rotations can be pre-computed for different pulse types, RF amplitude, and off-resonance. During the forward model evaluation, each RF rotation may be interpolated using this look-up table. The rotation may be computed differently for different pulse types. For example, some RF pulse families may admit analytical integration of the Bloch equations, while other RF pulses may require a numerical discretization of the ordinary differential equation, and may use numerical techniques such as Runge-Kutta methods.

Moreover, the per-voxel computation may be the core of the TFM analysis, where the tissue parameters may be numerically retrieved by solving a nonlinear least square problem.

### The Inverse Solver

If a method to compute Eqn. (1) is available, it may be possible to setup an inverse problem to retrieve the numerical tissue properties, e.g., by matching the predicted signal \tilde{s}ₗ(t) to the corresponding signal measured on the scanner sᵢ(t). For example, for a parametrization of the problem Θ, one may minimize a cost function

$$L ( Θ ) = {\sum }_{i} {‖ ( t , Θ ) - {s}_{i} ( t ) ‖}_{2}^{2} + R ( Θ ) \qquad ( 3 )$$

where the dependence of the forward model [symbol] on the parametrization Θ has been made explicit, and R is a regularization function.

The goal of the inverse problem may therefore be formulated as follows. Retrieve the system parameters Θ that minimize the cost function in Eqn. (3).

$${Θ}^{*} = {arg}_{Θ} min L ( Θ ) . \qquad ( 4 )$$

Considerations used to find a solution to Eqn. (4) include: what is a good parametrization Θ?; how to derive an efficient and practical implementation of Eqn. (1)?; and how to make the large-scale non-convex problem defined in Eqn. (4) tractable?

For example, the parametrization Θ may include the proton density D, and axial and transverse relaxation times (T₁ and T₂, respectively), sampled at points rₙ, where n=1 . . . N.

$$Θ = ( \begin{matrix}{D}^{( 1 )} \\ ⋮ \\ {D}^{( N )} \\ {T}_{1}^{( 1 )} \\ ⋮ \\ {T}_{1}^{( N )} \\ {T}_{2}^{( 1 )} \\ ⋮ \\ {T}_{2}^{( N )}\end{matrix} ) . \qquad ( 5 )$$

For example, the points r̅ₙ may discretize a Cartesian grid and may represent the centroids of the pixels (or voxels) of an image. This is the typical strategy in MRI.

TFM inversion may include a numerical solution of the minimization problem described by Eqn. (4). This is usually a large-scale and nonlinear numerical optimization problem. For example, in a typical MRI problem, the image may be discretized with 128³ or approximately 2×10⁶ voxels. If we assume 3 degrees of freedom per voxel (one complex density D and two real relaxation times T₁ and T₂), there are 6 million variables for which to solve.

In some embodiments, the problem may be solved using a Trust Region reFlective (TRF) formulation of the least square problem. Because the problem is highly nonlinear, the choice of the initial guess (how to initialize the vector Θ) often plays an important role. Here, we may initialize Θ by solving the same minimization problem only for the density D⁽ⁿ⁾, and fixing all other quantities as constants. For example, one may set T₁⁽ⁿ⁾=1 s, T₂⁽ⁿ⁾=0.1 s, 1≤n≤N in Eqn. (2). In this scenario, the minimization solves for

$${D}_{0} = ( \begin{matrix}{D}_{1}^{( 0 )} \\ ⋮ \\ {D}_{1}^{( N )}\end{matrix} ) \qquad ( 6 )$$

and initializes Θ for the full scale TFM inverse problem as:

$${Θ}_{0} = ( \begin{matrix}{D}_{0}^{( i )} \\ ⋮ \\ {D}_{0}^{( N )} \\ 1 \\ ⋮ \\ 1 \\ 0.1 \\ ⋮ \\ 0.1\end{matrix} ) . \qquad ( 7 )$$

Note that, for cases where the static field is highly homogeneous (ΔB<<B₀), the proposed initialization may be equivalent to initializing D₀ as a (2D or 3D) inverse Fourier transform of the measurement, e.g. using a Fast Fourier Transform or FFT technique. When the static field inhomogeneity is large, the proposed technique may not rely on the FFT technique. For example, if ΔB/B₀ is approximately equal to 100 ppm, the initialization of B₀ obtained through a full solution of the Bloch equations may differ from the initialization obtained via an inverse FFT. This difference may result in a more accurate and geometrically faithful initial estimate for the non-linear optimization in Eqn. (4). Consequently, it may prevent the solution from converging to local minima and may avoid geometrical distortions.

### Maxwell Regularization

In Eqn. (1), the signal collected by each sensor may be intrinsically weighted by the receiving characteristics of the sensor itself. The sensor may typically be a closed loop of a conducting material, and may exhibit a sensor-specific receiving pattern. Therefore, the spatial sensitivity distribution of the received signal strength may be a function of the direction and of the distance of the point emitting the signal (e.g., one magnetic spin). It illustrates how well the sensor receives signals from different angles or positions in space. This quantity (B̅_̅{̅l̅,̅ι̅}̅(r) in Eqn. (1)) is often referred to as coil sensitivity in MRI.

Because a coil sensitivity B̅_̅{̅l̅,̅ι̅}̅(r) is the spatial sensitivity distribution of the magnetic field received by an electrically conducting loop, it may be shown that B̅_̅{̅l̅,̅ι̅}̅(r) must satisfy Maxwell's equations. In TFM, B̅_̅{̅l̅,̅ι̅}̅(r) may be constrained to be a solution to Maxwell's equations. One possible implementation is to represent each coil sensitivity in terms of a set of basis functions computed via a randomized mode decomposition of point sources scattered around the region of interest.

In an alternative formulation, RF coils may be represented using equivalent surface currents on a surface mesh enclosing the region of interest. For example, one coil sensitivity B̅_̅{̅l̅,̅ι̅}̅(r) may be represented by the magnetic field due to an electric current distribution Jᵢ(r)=ΣₘJ_{i,m}λₘ(r), where λₘ, m=1 . . . M are div-conforming basis functions defined on a triangular tessellation of an enclosure of the RF coil region. In some embodiments, the basis functions λₘ may be: Rao-Wilton-Glisson basis functions (which are sometimes referred to as order-0 Raviart-Thomas basis function), their high-order extension Buffa-Christiansen functions. Note that it may be convenient to restrict these function spaces to the solenoidal subspace ∇·Jᵢ=0. This may be achieved by leveraging frameworks, such as Helmholtz decompositions, and its implementation via techniques such as loop-star or loop-tree decomposition, or quasi-Helmholtz projectors.

In some approaches, Jᵢ acts as a proxy for B̅_̅{̅l̅,̅ι̅}̅(r), and the coil sensitivity may be represented as a linear operator mapping surface currents onto magnetic fields: B̅_̅{̅l̅,̅ι̅}̅(r)=LJᵢ. The linear integral operator L may be computed with very high accuracy, and is available in implementations of a boundary element method (BEM) for electromagnetics problems. This approach may reduce the number of degrees of freedom of the optimization problem. Notably, for a 3D acquisition volume, the number of points at which B̅_̅{̅l̅,̅ι̅}̅(r) may be solved may be 128³ or approximately 2×10⁶, or 256³ or approximately 17×10⁶, while the number of coefficients in a Maxwell formulation is typically 200<M<2000.

For example, if a system has 8 receiving coils and the image size is 128³ or approximately 2×10⁶ voxels, the optimization problem may have 22 million optimization variables. With a Maxwell regularization, assuming for instance M equal to 1000 basis functions per coil sensitivity, the total number of optimization variables may be 2×10^{6×3+8×1000} or approximately 6×10⁶, when we solve for density and relaxation times voxel-by-voxel and the coil sensitivities have a Maxwell basis with 1000 elements.

### Diffusion as a Regularizer

By incorporating a diffusion model within a Bloch solver, the numerical optimization problem may be effectively regularized to invert for quantitative tissue properties, thereby enhancing the robustness of the solution to various sequence parameters. Bloch equations may be extended to account for diffusion terms in the Bloch-Torrey equations

$$\frac{d}{dt} \overline{m} = \overline{γ m} x \overline{B} - \frac{1}{{T}_{2}} {m}_{t} - \frac{1}{{T}_{1}} ( {m}_{z} - {m}_{0} ) \underline{z} + ∇ \cdot D ∇ m , \qquad ( 8 )$$

where D is the diffusion tensor.

By integrating the diffusion model, which characterizes the behavior of water molecules in tissue in a sample, the optimization problem benefits from additional constraints and regularization, which typically leads to more stable and accurate parameter estimation.

For example, one may set the diffusion tensor as a constant D=DI, where I is the identity matrix and D is the average diffusivity, e.g., D equals 2.3 mm²/ms for water at a room temperature of 25 C.

The diffusion model may introduce physical constraints that guide the inversion process and mitigate the sensitivity of the solution to specific sequence parameters, such as gradient strengths or acquisition duration. By explicitly considering the diffusion properties of the tissue, the model may compensate for variations in sequence parameters and may provide a more reliable estimation of the underlying tissue properties.

Through this regularization technique, the numerical optimization problem may achieve improved stability and robustness, thereby ensuring consistent and accurate results across different imaging sequences. The diffusion model may act as a regularizer that enhances the ability to extract quantitative tissue properties, regardless of variations in the sequence parameters.

Thus, the incorporation of a diffusion model within a Bloch solver may enable effective regularization of the numerical optimization problem, leading to more robust inversion for quantitative tissue properties. This regularization approach may mitigate the impact of sequence parameters, enhancing the reliability and consistency of the results. The disclosed computational techniques may provide significant progress for advancing the field of medical imaging, facilitating more accurate and robust characterization of tissue properties in diverse imaging scenarios.

### Auto-Differentiation

In some embodiments, auto-differentiation may used to efficiently solve large-scale nonlinear optimization problems, such as in the context of nonlinear least squares optimization using the TRF method. The disclosed computational techniques may leverage the capabilities of auto-differentiation, an automatic differentiation technique, to compute accurate derivatives of objective functions and constraints. By automatically computing the derivatives, the computational techniques may eliminate the need for manual or symbolic differentiation, thereby significantly reducing human effort and potential errors in the optimization process.

Furthermore, the disclosed computational techniques may employ the TRF method, a robust optimization technique that is suitable for handling nonlinear optimization problems with constraints. By combining the TRF method with auto-differentiation, the optimization process in the computational techniques may benefit from accurate derivative information, allowing for improved convergence rates and enhanced numerical stability. The TRF method, which may be adapted to various problem structures, employs a trust region framework that ensures sufficient progress while avoiding excessive changes in the model parameters.

The disclosed computational techniques may offer several advantages over conventional optimization techniques. Notably, the use of auto-differentiation may eliminate the need for hand-coding derivatives, resulting in reduced development time and improved code maintainability. Moreover, the TRR method, combined with auto-differentiation, may enable efficient handling of large-scale optimization problems by leveraging the ability to handle a large number of variables and constraints in the TRM method.

Thus, the disclosed computational techniques may provide an improved approach for solving large-scale nonlinear optimization problems through the use of auto-differentiation and the TRF method. By incorporating these techniques, the computational techniques may enhance the optimization process by automating derivative calculations and leveraging a robust optimization technique. This may enable efficient and accurate solutions to complex nonlinear least squares problems, thereby advancing the field of optimization in various industries and applications.

### Field Calibration

Eqn. (2) explicitly depends on the (position-dependent) static field inhomogeneity ΔB and on the RF transmit-field pattern B₁⁺. The minimization problem in Eqn. (4) may be solved for these quantities, as a calibration step. In order to solve for ΔB, a two-operation process may be used. Notably, a one-time high-accuracy calibration may be performed. Then, in-session fine tuning may be performed.

The first operation may include a high-accuracy, slow (e.g., on the order of multiple tens of minutes) calibration of the static magnetic field in the MR apparatus or scanner, such as by using an external magnetic-field mapping device. For example, the calibration may be done once (unless major system maintenance of the hardware is carried out, which potentially may change the field characteristics, e.g., shimming). Alternatively, the calibration may be repeated and updated, e.g., on a monthly basis. The goal of the calibration may be to provide a baseline map of AB, which may be refined at scan time. This operation may be carried out on a large phantom, which may cover the entire region of interest. Many individual images may be collected with a conventional sequence, e.g., a gradient echo (GRE) sequence, and different echo times (TE). If a sufficient number of unique TE values is available, and if the difference between successive TE is small enough to ensure that, given an arbitrary position r̅ within the phantom, the phase difference of the image at r̅ for two consecutive TE values may be Δφ<2π (for each image, the phase may be known modulus 2π). Note that techniques such as multiple-gradient echo B₀ field mapping may be used to retrieve the spatial distribution of ΔB. For example, a sequence of eleven 3D images may be collected, with echo times linearly spaced between 2 and 4 ms, 5 mm resolution, and a high receiver bandwidth (e.g., 1000 Hz/pixel). A linear fit of the unwrapped phase may be obtained voxel-wise, to estimate the static field inhomogeneity ΔB(r̅). An optional smoothing operation may be carried out, e.g., by projecting ΔB(r̅) on a subspace of spherical harmonics. Notably, one may limit the maximum degree of the spherical harmonic representation to L equals 6.

The second operation may be repeated at scan time (on the patient) and may aim to fine tuning the calibration of ΔB to account for effects, such as subject-specific effects or thermal drift of the magnetic field. The magnetic-field distribution obtained in the first operation may be used as a prior, and this may allow the number of images necessary and the resolution of each image to be relaxed. For example, two single echo images may be collected at TE equals 2 ms and TE equals 4 ms, with 8 mm resolution, and knowledge of the prior AB may remove the uncertainty about the branch of the multi-valued phase function. Because of the relaxed requirements in terms of the number of images and the resolution, this calibration operation may be performed in approximately 5 s and is, therefore, possible at scan time.

Note that both operations described above may require retrieving ‘image; data from measurements. For example, two approaches may be possible, depending on the expected level of field inhomogeneity within the field of view. For mild inhomogeneities (ΔB/B₀<100 ppm), an inverse FFT technique may provide a good estimate. However, for severe inhomogeneities (ΔB/B₀>100 ppm), a Bloch equation-based optimization problem (Eqn. (4)) may be solved with optimization variables

$$Θ = ( \begin{matrix}Δ {B}^{( 1 )} \\ ⋮ \\ Δ {B}^{( N )}\end{matrix} ) . \qquad ( 9 )$$

Note that in some embodiments, a factory-magnetic field map measured by a field-mapping device may be used to initialize the solution to optimization problem. Alternatively, or additionally, for Bₗ⁺ mapping, other mapping techniques may be used initially, such as the slow gold standard of transmitting RF pulses at a range of RF powers and analyzing the resulting measured signals to determine the power required to reach a desired flip-angle (such as 90 or 180°). The relationship between the flip-angle α and Bₗ⁺ at each voxel location is given by

$$α = γ {\int }_{0}^{{T}_{RF}} {B}_{1}^{+} ( \overline{r} , t ) dt , \qquad ( 10 )$$

where γ is the gyromagnetic ratio of the nucleus to be imaged, and T_{RF} is the duration of the RF pulse excitation. For example, γ is approximately 42.576 MHz/T for water molecules, and T_{RF} can vary in a range between 0.1 and 10 ms.

Given the acquired data, an analysis technique, such as Levenberg-Marquardt, may be used to fit the expected sinusoidal signal evolution. In order to eliminate effects of T₁ recovery, the repetition time T_{R} of this measurement may be at least 5 times the T₁ of the test object the mapping is performed on. This may result in a calibration procedure having a duration on the order of minutes. Besides the speed, this analysis technique may also be limited to the spatial extent of the mapping object and may assume that B₀ has minimal effect on the RF excitation. In embodiments with large B₀ inhomogeneity, a joint Bloch equation-based optimization problem may be used, which solves for B₀ and Bₗ⁺ simultaneously.

A faster implemention may use approximate B₀/Bₗ⁺ field maps generated from the known hardware geometry using an electromagnetics simulator, such as COMSOL (from COSMOL, Inc., of Burlington, Massachusetts). The analysis may be refined using a magnetic-field mapping device that directly measures the magnetic field strengths. During online reconstruction, the TFM framework may jointly solve for the tissue parameters (such as the proton density or PD, T₁ and T₂) along with the magnetic-field maps (B₀/Bₗ⁺) to correct for small magnetic-field variations from the simulated magnetic-field map.

### Motion Reconstruction

The disclosed computational techniques may support motion compensation reconstruction by modeling the temporal evolution of the position of each voxel as a low-rank problem. The computational techniques may aim to address the challenges posed by motion-induced artifacts in imaging systems, particularly in dynamic imaging scenarios where motion is prevalent. By considering the temporal dimension of the acquired data, the computational techniques may capture the dynamic nature of the voxel positions over time.

In order to achieve this goal, the computational techniques may use a low-rank modeling approach, leveraging the inherent correlation and temporal smoothness of voxel positions. By representing the voxel positions as a low-rank matrix, the computational techniques may exploit the fact that voxel trajectories often exhibit similar patterns and may be effectively described by a small number of underlying basis functions.

By formulating the voxel position estimation problem as a low-rank problem, the computational techniques may enable robust and accurate motion compensation reconstruction. Notably, the computational techniques may effectively separate the motion-induced artifacts from the underlying static structures, thereby facilitating the reconstruction process and improving the quality of the final images. For example, techniques such as neural radiance fields (nerf) or deep implicit statistical shape models (dissm) may be used to efficiently model and regularize motion estimation.

The disclosed computational techniques may offer several advantages over traditional motion compensation techniques. Notably, by explicitly modeling the temporal evolution of voxel positions, the computational techniques may provide a comprehensive framework to address complicated motion scenarios. Moreover, the low-rank formulation may enhance the robustness of the reconstruction process, thereby enabling effective handling irregular or incomplete motion data.

Integration with the Pulse Sequence Framework

In the computational techniques, the numerical framework may have been seamlessly integrated with a proprietary MRI scanner and the pulse sequence framework, thereby resulting in a comprehensive solution that enables robust support for arbitrary acquisition strategies. By leveraging this integration, the system may efficiently and accurately control the acquisition process, thereby allowing for flexible and customizable imaging protocols. This tight integration between the numerical framework, the MRI scanner, and the pulse sequence framework may ensure optimal data acquisition, maximizing the potential of the MRI system and empowering researchers and clinicians with the ability to explore innovative imaging techniques and adapt to diverse study requirements.

For example, the TFM framework may receive as input the raw RF/gradient waveforms and readout times from the pulse sequence framework. Then, these waveforms may be numerically integrated to compute the necessary durations and waveform moments used in the forward-model simulation. For each block, the following moments may be used: from the RF pulse to the echo, from echo to the readouts, and from the echo to the next RF pulse.

In some embodiments, RF/gradient waveforms and readout events may be generated using the pulse-sequence framework. Then, TFM may integrate the following per block: from the RF pulse to the echo, from the echo to the readouts, from the echo to the next RF pulse. The simulation may only use the duration between events and the integrated waveform (moment). This may enable rapid simulating/inverting arbitrary pulse sequences.

In some embodiments, the integration is achieved by generating the pulse sequence for a specific application in the numerical optimization framework itself by selecting sampling patterns and the number of samples. As a result, the forward problem may be well conditioned for the desired parameter set to be solved in the inversion and the number of samples may be reduced or minimal. This process may itself be an optimization process in which samples may be iteratively added, removed, and changed in temporal order in order to achieve an optimal acquisition pattern. Note that this optimization may be performed by simulation on a virtual phantom.

In order to further optimize the acquisition for a particular body part, a range of possible tissue parameters may be assumed or taken from prior measurement of the patient or patient population. Moreover, optimized acquisition parameters may be stored or saved, so that the optimization does not have to be repeated. Furthermore, ranges of tissue parameters may be estimated from simpler pre-scans or prior TFM scans in the same session.

Application-specific optimization models may be used for certain acquisitions, e.g., if it is known that a certain tissue at a certain spatial resolution exhibits multiple large fractions of spin species with short and long T₁ in the same voxel, the acquisition may be tailored so that the inversion can solve for multiple T₁ relaxation parameters. Similarly, if the previous knowledge indicates very short T₁ or T₂ values, the optimal acquisition strategy may be very different.

### Q Super Block Decomposition

In order to reduce the computational burden of the simulations, sequences exhibiting a periodic temporal evolution of the magnetization may be efficiently compressed. Here we introduce the concept of a Q Super Block (QSB).

Let's denote with X the in-plane resolution, corresponding to the number of samples per read line, with Y the resolution in the phase direction (typically, Y equals X), and with Z the number of partitions (Z equals 1 for 2D acquisitions). Moreover, let's denote the total number of voxels V as XYZ. The Jacobian and its adjoint of the TFM inverse problem may be represented as the outer product of several operators, defined as follows. The echo magnetization, M∈C^{VxLP}, may be is the voxel-wise magnetization at echo time, where L is the total number of acquired echoes and P is the number of nonlinear parameters per voxel (typically, P equals 2). Moreover the encoding operators may be E_{y} ∈C^{YxL} and E_{Z}∈C^{ZxL}. Furthermore, the echo to sample may be S∈C^{VxS}, where S, the number of samples per line (typically, S equals X), may be an outer product expanding the signal at echo time to the signal at each sample location. Additionally, the coil sensitivity maps may be S∈C^{VxC}, where C is the number of receiving coils, which may collect voxel-wise coil sensitivity maps.

From these operators, note that the cost may be dominated by M, which scales as O(X⁵) (the total number of lines may scale as L equal O(X²).

By carefully engineering the acquisition strategy, such that the echo magnetization repeats periodically during the acquisition, it may be possible to reduce this cost from O(X⁵) to O(X⁴). This may be formalized as a QSB. Notably, the acquisition may have a periodic magnetization pattern, which repeats R times. Therefore, each QSB may include L_{B} equal to L/R echoes, and the echo magnetization may be fully represented by the echo magnetization of one single QSB (or M_{B} ∈C^{VxL}^{_{B}}^{P}. Typically, the number of lines per block is in the range of L_{B} of approximately 100-1000. Note that the other operators may not be periodic and may not get reduced.

Furthermore, instead of evaluating matrix operations, we may recast each operator as a high-dimensional tensor. For example, M_{B} may be rewritten as M_{B} ∈C^{XxYxZxL}^{_{B}}^{xP}, E_{Y} may be rewritten as E_{y} ∈C\hat{ }YxRxL_{B}, etc. By rewriting the signal in tensor form rather than in matrix form, it may be possible to represent the Jacobian and adjoint Jacobian operators as tensor contractions. Using this approach, it may be possible to resort to techniques such as opt_einsum, which may optimize the contraction order of the expression and may dispatch many operations to canonical basic linear algebra subroutines (BLAS) or other specialized routines. This brings a typical speed-up factor of the order of approximately 10²-10³.

Thus, by introducing the QSB and by factorizing it as a tensor contraction operation, it may be possible to reduce the asymptotic complexity from O(X⁵) to O(X⁴). For example, for a 256³ resolution, this may reduce the memory footprint by a factor 256. Moreover, by introducing the QSB and by factorizing it as a tensor contraction operation, it may be possible to find a close-to-optimal contraction order. This operation may reduce the computational time of the simulation by a factor approximately 10²-10³. This may enable efficient modeling and solution of full 3D problems on a computing workstation equipped with a modern GPU unit. For example, it may be possible to invert for quantitative MRI at a 1 mm isotropic resolution acquisition of a human brain with one H100 GPU equipped with 80 GB of RAM.

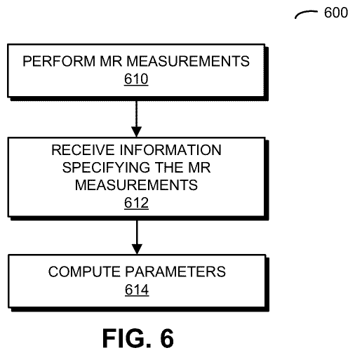

We now further describe the computational techniques. FIG. 6 presents a flow diagram illustrating an example of a method for computing parameters associated with voxels in a sample, which may be performed by a computer system (such as computer system 116 in FIG. 1).

During operation, the computer system may perform MR measurements (operation 610) on a sample, where performing the MR measurements may include providing an RF sequence to an MR scanner. The RF sequence may include multiple instances of pulse sequences that correspond to a dynamic magnetization state in the sample, and a given pulse sequence may include more than a predefined number of pulses (such as 100 pulses). Then, the computer system may receive, from the MR scanner, information specifying the MR measurements (operation 612). Next, the computer system may compute parameters (operation 614) associated with voxels in the sample based at least in part on the MR measurements, where computing the parameters may include solving an inverse problem for the parameters given the MR measurements, and where the RF sequence may encode second information in the MR measurements that allows the parameters for the voxels to be computed.

Moreover, the RF sequence may include time intervals between the instances of the pulse sequences.

Furthermore, the sample may be in a known magnetization state in each of the instances of the pulse sequence, and the known magnetization state may be different than magnetic polarization along an external magnetic field associated with the MR scanner (which is sometimes referred to as a ‘fully relaxed magnetic state’).

Additionally, the MR parameters in each of the voxels may include: a proton density, T₁, and T₂.

In some embodiments, performing the MR measurements (operation 710) may include line encoding of different voxels in the sample. This may allow the Fourier or k-space-based properties of the sample in the dynamic magnetization state to be measured without perturbing the dynamic magnetization state.

Note that the dynamic magnetization state may correspond to three times a number of pulses in a given instance of the pulse sequence.

In some embodiments of method 200 (FIG. 2) and/or 600, there may be additional or fewer operations. Furthermore, the order of the operations may be changed, and/or two or more operations may be combined into a single operation.

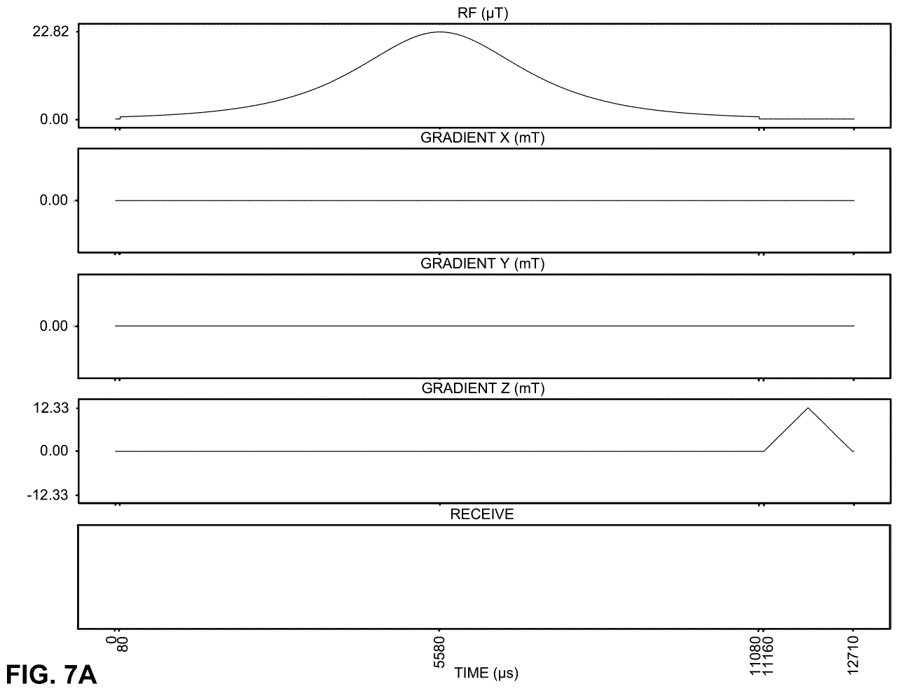

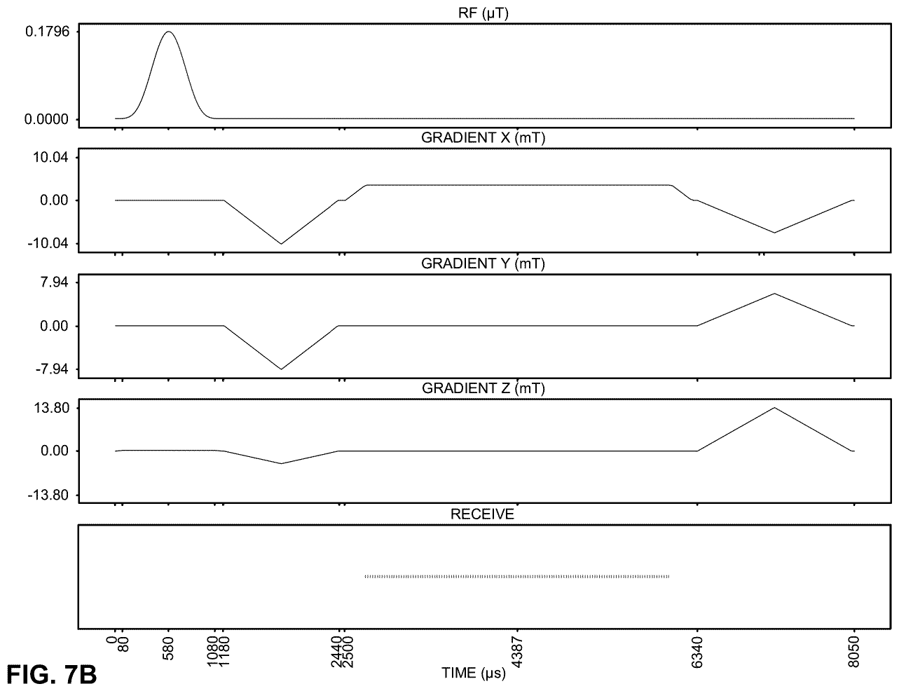

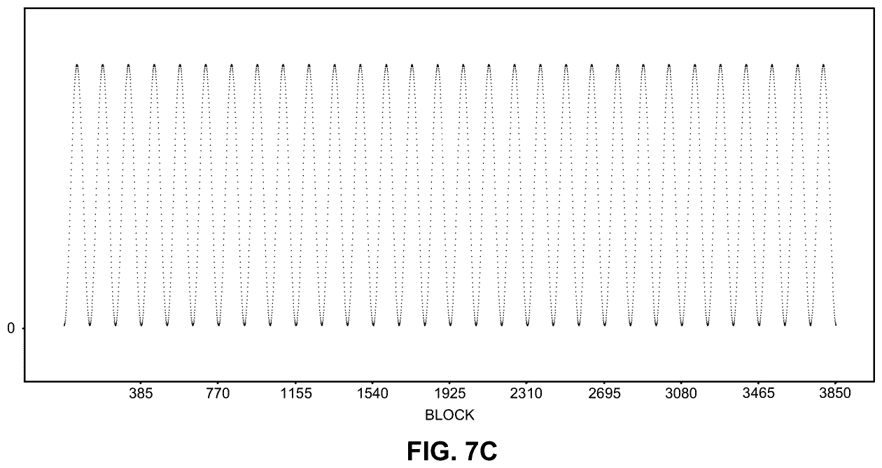

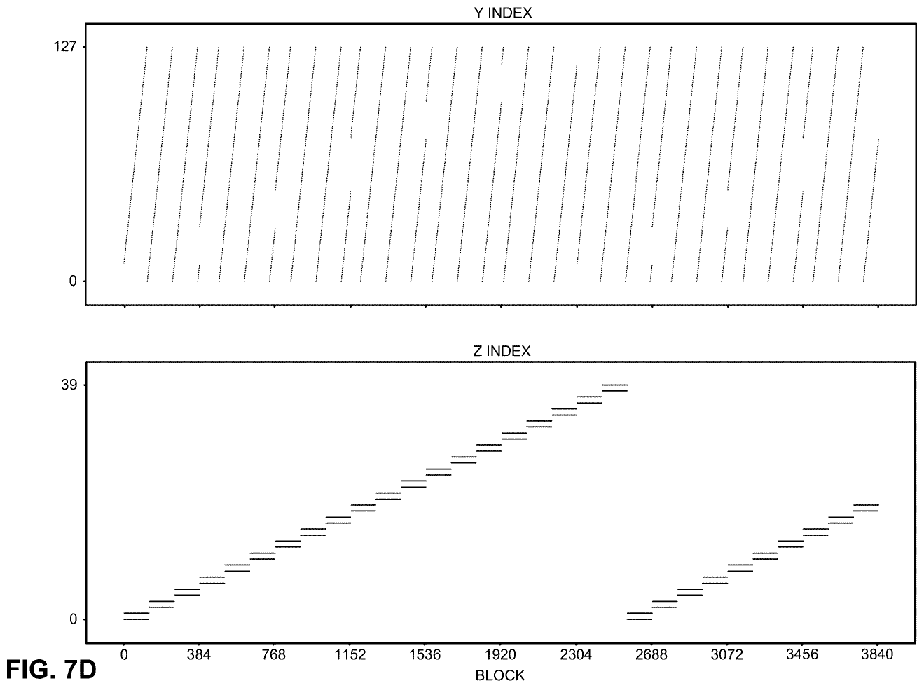

FIGS. 7A-D presents drawings illustrating examples of RF sequences and dynamic magnetization states used during QSB decomposition in the system in FIG. 1. Notably, FIG. 7A illustrates 1x of an inversion pulse. This adds T₁ information in the dynamic magnetization state. FIG. 7B illustrates approximately 300x excitation pulses. The RF flip angle is smoothly varied to add T₂ information in the dynamic magnetization state, which is shown in FIG. 7C. This may extend the dynamic magnetization state and may be where line encoding/readout is performed. Note that the time interval between pulse sequences in a given RF sequence may be approximately 0.5 s in duration, which may allow for T₂ recovery. FIG. 7D illustrates 1-3 repeats (each approximately 300×) of the pulse sequences in an RF sequence with different line encoding patterns.

Note that FIGS. 7A-7C may include the QSB and may encode the dynamic magnetization state. Moreover, FIG. 7D may be used to measure this dynamic magnetization state to generate a full k-space. The line encoding moments may balanced and, thus, may not affect the dynamic magnetization state. This may allow efficient simulation of the parameters associated with the voxels in TFM, because the dynamic magnetization state only needs to be simulated for the first QSB (as illustrated in FIGS. 7A-7C).

### GPU and Multi-GPU Support

The numerical framework in the disclosed computational technique may facilitate fast computation of large-scale 3D problems by harnessing the power of GPUs and multi-GPU configurations. The Q Super Block decomposition may be fully parallelizable across voxels. For example, each voxel may be assigned to a GPU and only the resulting measurement vectors may be transferred between GPUs. For each measurement vector transfer of size O(N), each GPU may perform (N²) work. Thus, the total performance and memory of the system may scale nearly linearly with the number of GPUs. Furthermore, the Q Super Block decomposition may be better conditioned than the naïve BLOCH integration, so reduced precision floating point numbers, such as 16-bit, may be used to with negligible impact on measurement accuracy. By implementing GPU support, this numerical framework may enable real-time imaging simulation directly on an MRI scanner, thereby enhancing the efficiency of medical imaging workflows and enabling prompt decision-making. The numerical framework may address the inherent limitation of GPU memory by incorporating a multi-GPU implementation, which may allow for the handling of very large 3D problems. For example, the system may effectively represent and solve a problem with dimensions of 256×256×256 by using a configuration consisting of four H100 GPUs (from Nvidia Corp., of Santa Clara, California), each providing 80 GB memory.

The disclosed system and computational techniques may significantly improve computational capabilities, enabling the rapid analysis and solution of complicated problems that were previously unattainable. By efficiently distributing computational tasks across multiple GPUs, the framework may achieve optimal utilization of available resources, resulting in reduced computation times and enhanced scalability. These capabilities may be achieved by using custom sharding maps.

The integration of GPU and multi-GPU support in the disclosed numerical framework may provide a practical solution to the challenges of fast computation for large-scale 3D problems. The present disclosure aims to cover the system and the computation techniques, including their components, implementation details, and applications.

In some embodiments, the Q Super Block Decomposition may be a fully parallelizable computation. For example, chunks of voxels may be assigned to each computing unit (GPU). Then, forward model integration may be performed on each computing unit with no intermediate data transfer required. The final vector measurement result may then be transferred back to the primary computing unit.

We now further describe an electronic device that performs at least some of the operations in the computation technique. FIG. 8 presents a block diagram illustrating an electronic device 800 in system 100 (FIG. 1), such as computer 116 (FIG. 1) or another of the computer-controlled components in system 100, such as source 110 or measurement device 114 (FIG. 1). This electronic device includes a processing subsystem 810, memory subsystem 812, and networking subsystem 814. Processing subsystem 810 may include one or more devices configured to perform computational operations and to control components in system 100 (FIG. 1). For example, processing subsystem 810 may include one or more microprocessors or central processing units (CPUs), one or more GPUs, application-specific integrated circuits (ASICs), microcontrollers, programmable-logic devices (such as a field programmable logic array or FPGA), and/or one or more digital signal processors (DSPs).

Memory subsystem 812 may include one or more devices for storing data and/or instructions for processing subsystem 810 and networking subsystem 814. For example, memory subsystem 812 may include dynamic random access memory (DRAM), static random access memory (SRAM), and/or other types of memory. In some embodiments, instructions for processing subsystem 810 in memory subsystem 812 include one or more program modules or sets of instructions (such as program instructions 824), which may be executed in an operating environment (such as operating system 822) by processing subsystem 810. Note that the one or more computer programs may constitute a computer-program mechanism or a program module (i.e., software). Moreover, instructions in the various modules in memory subsystem 812 may be implemented in: a high-level procedural language, an object-oriented programming language, and/or in an assembly or machine language. Furthermore, the programming language may be compiled or interpreted, e.g., configurable or configured (which may be used interchangeably in this discussion), to be executed by processing subsystem 810.

In addition, memory subsystem 812 may include mechanisms for controlling access to the memory. In some embodiments, memory subsystem 812 includes a memory hierarchy that comprises one or more caches coupled to a memory in electronic device 800. In some of these embodiments, one or more of the caches is located in processing subsystem 810.

In some embodiments, memory subsystem 812 is coupled to one or more high-capacity mass-storage devices (not shown). For example, memory subsystem 812 may be coupled to a magnetic or optical drive, a solid-state drive, or another type of mass-storage device. In these embodiments, memory subsystem 812 may be used by electronic device 800 as fast-access storage for often-used data, while the mass-storage device is used to store less frequently used data.

In some embodiments, memory subsystem 812 includes a remotely located archive device. This archive device may be a high-capacity network attached mass-storage device, such as: network attached storage (NAS), an external hard drive, a storage server, a cluster of servers, a cloud-storage provider, a cloud-computing provider, a magnetic-tape backup system, a medical records archive service, and/or another type of archive device. Moreover, processing subsystem 810 may interact with the archive device via an application programming interface to store and/or access information from the archive device. Note that memory subsystem 812 and/or electronic device 800 may be compliant with the Health Insurance Portability and Accountability Δct.

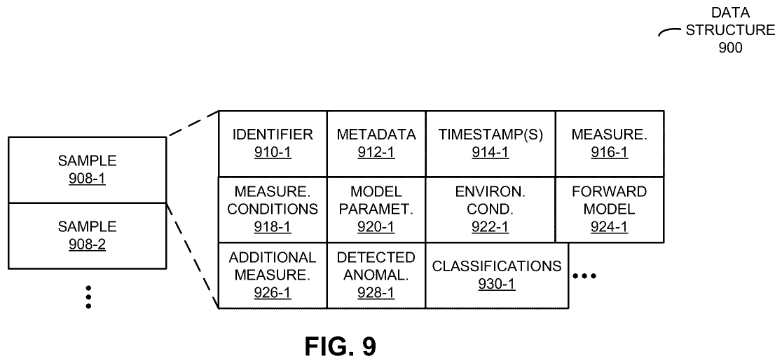

An example of the data stored (locally and/or remotely) in memory subsystem 812 is shown in FIG. 9, which presents a drawing illustrating an example of a data structure 900 that is used by electronic device 800 (FIG. 8). This data structure may include: an identifier 910-1 of sample 908-1 (such as an individual), metadata 912 (such as age, gender, biopsy results and diagnosis if one has already been made, other sample information, demographic information, family history, etc.), timestamps 914 when data was acquired, received measurements 916 (such as MR signals and, more generally, raw data), excitation and measurement conditions 918 (such as an external magnetic field, an optional gradient, an RF pulse sequence, an MR apparatus, a location, machine-specific characteristics such as magnetic-field inhomogeneity, RF noise and one or more other system imperfections, signal-processing techniques, registration information, synchronization information such between measurements and a heartbeat or breathing pattern of an individual, etc.), and/or determined model parameters 920 (including voxel sizes, speed, resonant frequency or a type of nuclei, T₁ and T₂ relaxation times, segmentation information, classification information, etc.), environmental conditions 922 (such as the temperature, humidity and/or barometric pressure in the room or the chamber in which sample 908-1 was measured), forward model 924, one or more additional measurements 926 of physical properties of sample 908-1 (such as weight, dimensions, images, etc.), optional detected anomalies 928 (which may include particular voxel(es) associated with the one or more of detected anomalies 928), and/or optional classifications 930 of the one or more detected anomalies 928. Note that data structure 900 may include multiple entries for different measurements.

In one embodiment, data in data structure 900 is encrypted using a block-chain or a similar cryptographic hash technique to detect unauthorized modification or corruption of records. Moreover, the data may be anonymized prior to storage so that the identity of an individual associated with a sample is anonymous unless the individual gives permission or authorization to access or release the individual's identity.

Referring back to FIG. 8, networking subsystem 814 may include one or more devices configured to couple to and communicate on a wired, optical and/or wireless network (i.e., to perform network operations and, more generally, communication), including: control logic 816, an interface circuit 818, one or more antennas 820 and/or input/output (I/O) port 828. (While FIG. 8 includes one or more antennas 820, in some embodiments electronic device 800 includes one or more nodes 808, e.g., a pad or connector, which may be coupled to one or more antennas 820. Thus, electronic device 800 may or may not include one or more antennas 820.) For example, networking subsystem 814 may include a Bluetooth networking system (which may include Bluetooth Low Energy, BLE or Bluetooth LE), a cellular networking system (e.g., a 3G/4G/5G network such as UMTS, LTE, etc.), a universal serial bus (USB) networking system, a networking system based on the standards described in IEEE 802.11 (e.g., a Wi-Fi networking system), an Ethernet networking system, and/or another networking system.

Moreover, networking subsystem 814 may include processors, controllers, radios/antennas, sockets/plugs, and/or other devices used for coupling to, communicating on, and handling data and events for each supported networking system. Note that mechanisms used for coupling to, communicating on, and handling data and events on the network for each network system are sometimes collectively referred to as a ‘network interface’ for network subsystem 814. Moreover, in some embodiments a ‘network’ between components in system 100 (FIG. 1) does not yet exist. Therefore, electronic device 800 may use the mechanisms in networking subsystem 814 for performing simple wireless communication between the components, e.g., transmitting advertising or beacon frames and/or scanning for advertising frames transmitted by other components.

Within electronic device 800, processing subsystem 810, memory subsystem 812, networking subsystem 814 may be coupled using one or more interconnects, such as bus 826. These interconnects may include an electrical, optical, and/or electro-optical connection that the subsystems may use to communicate commands and data among one another. Although only one bus 826 is shown for clarity, different embodiments may include a different number or configuration of electrical, optical, and/or electro-optical connections among the subsystems.

Electronic device 800 may be (or can be) included in a wide variety of electronic devices. For example, electronic device 800 may be included in: a tablet computer, a smartphone, a smartwatch, a portable computing device, a wearable device, test equipment, a digital signal processor, a cluster of computing devices, a laptop computer, a desktop computer, a server, a subnotebook/netbook and/or another computing device.

Although specific components are used to describe electronic device 800, in alternative embodiments, different components and/or subsystems may be present in electronic device 800. For example, electronic device 800 may include one or more additional processing subsystems, memory subsystems, and/or networking subsystems. Additionally, one or more of the subsystems may not be present in electronic device 800. Moreover, in some embodiments, electronic device 800 may include one or more additional subsystems that are not shown in FIG. 8.

Although separate subsystems are shown in FIG. 8, in some embodiments, some or all of a given subsystem or component may be integrated into one or more of the other subsystems or components in electronic device 800. For example, in some embodiments program instructions 824 are included in operating system 822. In some embodiments, a component in a given subsystem is included in a different subsystem. Furthermore, in some embodiments electronic device 800 is located at a single geographic location or is distributed over multiple different geographic locations.

Moreover, the circuits and components in electronic device 800 may be implemented using any combination of analog and/or digital circuitry, including: bipolar, PMOS and/or NMOS gates or transistors. Furthermore, signals in these embodiments may include digital signals that have approximately discrete values and/or analog signals that have continuous values. Additionally, components and circuits may be single-ended or differential, and power supplies may be unipolar or bipolar.

An integrated circuit may implement some or all of the functionality of networking subsystem 814 (such as a radio) and, more generally, some or all of the functionality of electronic device 800. Moreover, the integrated circuit may include hardware and/or software mechanisms that are used for transmitting wireless signals from electronic device 800 and receiving signals at electronic device 800 from other components in system 100 (FIG. 1) and/or from electronic devices outside of system 100 (FIG. 1). Aside from the mechanisms herein described, radios are generally known in the art and hence are not described in detail. In general, networking subsystem 814 and/or the integrated circuit may include any number of radios. Note that the radios in multiple-radio embodiments function in a similar way to the radios described in single-radio embodiments.

While some of the operations in the preceding embodiments were implemented in hardware or software, in general the operations in the preceding embodiments may be implemented in a wide variety of configurations and architectures. Therefore, some or all of the operations in the preceding embodiments may be performed in hardware, in software or both.

In addition, in some of the preceding embodiments there are fewer components, more components, a position of a component is changed and/or two or more components are combined.

While the preceding discussion illustrated the computation technique to solve a vector wave equation, in other embodiments the computation technique may be used to solve a scalar equation. For example, an acoustic wave equation may be solved in an arbitrary inhomogeneous media based on ultrasound measurements using a forward model. (Thus, in some embodiments the excitation may be mechanical.) Note that the acoustic coupling in ultrasound measurements may dependent on the operator (i.e., the ultrasound measurements may be pressure dependent). Nonetheless, a similar approach may be used to: improve ultrasound imaging, determine 3D structure, facilitate improved presentation, etc.

In the preceding description, we refer to ‘some embodiments.’ Note that ‘some embodiments’ describes a subset of all of the possible embodiments, but does not always specify the same subset of embodiments. Moreover, note that numerical values in the preceding embodiments are illustrative examples of some embodiments. In other embodiments of the computation techniques, different numerical values may be used.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. A computer system, comprising:
an interface circuit;
a processor configured to execute program instructions; and
memory storing the program instructions, wherein, when executed by the processor, the program instructions cause the computer system to perform operations comprising:
performing magnetic-resonance (MR) measurements on a sample, wherein performing the MR measurements comprises providing a radio-frequency (RF) sequence to an MR scanner, wherein the RF sequence comprises multiple instances of pulse sequences corresponding to a dynamic magnetization state in a sample, and wherein a given pulse sequence comprises more than a predefined number of pulses;
receiving, from the MR scanner, information specifying the MR measurements; and
computing parameters associated with voxels in the sample based at least in part on the MR measurements, wherein the computing of the parameters comprises solving an inverse problem for the parameters given the MR measurements, and wherein the RF sequence encodes second information in the MR measurements that allows the parameters for the voxels to be computed.

2. The computer system of claim 1, wherein the predefined number of pulses is greater than 100 pulses.

3. The computer system of claim 1, wherein the RF sequence comprises time intervals between the instances of the pulse sequences.

4. The computer system of claim 1, wherein the sample is in a known magnetization state in each of the instances of the pulse sequence, and the known magnetization state is different than magnetic polarization along an external magnetic field associated with the MR scanner.

5. The computer system of claim 1, wherein the MR parameters in each of the voxels comprises: a proton density, a longitudinal relaxation time or a spin-lattice relaxation time (T₁), and a transverse relaxation time or a spin-spin relaxation time (T₂).

6. The computer system of claim 1, wherein the performing of the MR measurements comprises line encoding of different voxels in the sample.

7. The computer system of claim 1, wherein the dynamic magnetization state corresponds to three times a number of pulses in a given instance of the pulse sequence.

8. A method for computing parameters associated with voxels in a sample, comprising:
by a computer system:
performing magnetic-resonance (MR) measurements on the sample, wherein performing the MR measurements comprises providing a radio-frequency (RF) sequence to an MR scanner, wherein the RF sequence comprises multiple instances of pulse sequences corresponding to a dynamic magnetization state in a sample, and wherein a given pulse sequence comprises more than a predefined number of pulses;
receiving, from the MR scanner, information specifying the MR measurements; and
computing the parameters associated with the voxels in the sample based at least in part on the MR measurements, wherein the computing of the parameters comprises solving an inverse problem for the parameters given the MR measurements, and wherein the RF sequence encodes second information in the MR measurements that allows the parameters for the voxels to be computed.

9. The method of claim 8, wherein the predefined number of pulses is greater than 100 pulses.

10. The method of claim 8, wherein the RF sequence comprises time intervals between the instances of the pulse sequences.

11. The method of claim 8, wherein the sample is in a known magnetization state in each of the instances of the pulse sequence, and the known magnetization state is different than magnetic polarization along an external magnetic field associated with the MR scanner.

12. The method of claim 8, wherein the MR parameters in each of the voxels comprises: a proton density, a longitudinal relaxation time or a spin-lattice relaxation time (T₁), and a transverse relaxation time or a spin-spin relaxation time (T₂).

13. The method of claim 8, wherein the performing of the MR measurements comprises line encoding of different voxels in the sample.

14. The method of claim 8, wherein the dynamic magnetization state corresponds to three times a number of pulses in a given instance of the pulse sequence.

15. A non-transitory computer-readable storage medium for use in conjunction with a computer system, the computer-readable storage medium configured to store a program module that, when executed by the computer system, causes the computer system to perform operations comprising:
performing magnetic-resonance (MR) measurements on a sample, wherein performing the MR measurements comprises providing a radio-frequency (RF) sequence to an MR scanner, wherein the RF sequence comprises multiple instances of pulse sequences corresponding to a dynamic magnetization state in a sample, and wherein a given pulse sequence comprises more than a predefined number of pulses;
receiving, from the MR scanner, information specifying the MR measurements; and
computing parameters associated with voxels in the sample based at least in part on the MR measurements, wherein the computing of the parameters comprises solving an inverse problem for the parameters given the MR measurements, and wherein the RF sequence encodes second information in the MR measurements that allows the parameters for the voxels to be computed.

16. The non-transitory computer-readable storage medium of claim 15, wherein the predefined number of pulses is greater than 100 pulses.

17. The non-transitory computer-readable storage medium of claim 15, wherein the RF sequence comprises time intervals between the instances of the pulse sequences.

18. The non-transitory computer-readable storage medium of claim 15, wherein the sample is in a known magnetization state in each of the instances of the pulse sequence, and the known magnetization state is different than magnetic polarization along an external magnetic field associated with the MR scanner.

19. The non-transitory computer-readable storage medium of claim 15, wherein the performing of the MR measurements comprises line encoding of different voxels in the sample.

20. The non-transitory computer-readable storage medium of claim 15, wherein the dynamic magnetization state corresponds to three times a number of pulses in a given instance of the pulse sequence.
